(19) United States
(12) Patent Application Publication
(10) Pub. No.: US 2007/0026685 A1
(43) Pub. Date: Feb. 1, 2007

(54) Mask structure, method of forming the mask structure, method of forming a pattern using the mask structure and method of forming contacts in a semiconductor device using the mask structure

(75) Inventors: Yong-Kug Bae, Hwaseong-si (KR); Ji-Yong You, Suwon-si (KR); Yong-Sun Ko, Suwon-si (KR); Seung-Won Seong, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/481,177

(22) Filed: Jul. 6, 2006

(30) Foreign Application Priority Data
Jul. 11, 2005 (KR) 2005-0062215

(51) Int. Cl. H01L 21/302

(52) U.S. Cl. 438/736; 438/738; 438/737

(57) ABSTRACT

A mask structure may include a first mask pattern and a second mask pattern formed on an object. When the object includes a first material, the first and the second mask patterns may include a second material and a third material, respectively. The second mask pattern may have at least two openings that expose portions of the object adjacent to sides of the first mask pattern. Because the mask structure has the first and the second mask patterns, desired structures, for example, recesses, trenches, contact holes or patterns may be more precisely formed on or through the object. For example, the first mask pattern may protect the object in an etching process for forming contact holes so that the contact holes may not be connected to each other, for example, when the contact holes have bar shapes or line shapes.

### PRIORITY CLAIM

A claim of priority is made under 35 USC § 119 to Korean Patent Application No. 2005-62215 filed on Jul. 11, 2005, the contents of which are herein incorporated by reference in their entirety.

### BACKGROUND OF THE INVENTION

1. Field of the Invention

Example embodiments of the present invention relate to a mask structure, a method of forming a mask structure, a method of forming a pattern using a mask structure and a method of forming contacts in a semiconductor device using a mask structure. For example, example embodiments of the present invention relate to a mask structure for more accurately forming a desired structure, a method of forming a mask structure, a method of forming a pattern using a mask structure and a method of forming contacts in a semiconductor device using a mask structure.

2. Description of the Related Art

Semiconductor memory devices may be generally divided into volatile semiconductor memory devices, for example, a dynamic random access memory (DRAM) device and a static random access memory (SRAM) device, and nonvolatile semiconductor memory devices, for example, an erasable programmable read only memory (EPROM) device, an electrically erasable programmable read only memory (EEPROM) and a flash memory device.

As semiconductor devices have been widely employed in various electric and electronic apparatuses, improvement in response speed, storage capacity, and/or higher integration degree have been made. A higher integrated semiconductor device requires finer patterns and/or contacts. However, finer patterns and/or contacts may not be accurately formed because a photolithography process to form the fine patterns and/or contacts may be limited. One method of overcoming this limitation is to form contacts in semiconductor devices to have line shapes or bar shapes instead of circular shapes. However, contacts having a line or a bar shape may be connected to each other because an insulation layer between the contact holes may be etched during an etching process.

FIG. 1 is an electron microscopic picture illustrating a contact in a conventional semiconductor device.

As shown in FIG. 1, when contact holes have bar shapes or line shapes by partially etching an insulation interlayer 15, a portion of the insulation interlayer 15 between the contact holes may be consumed and have a reduced width W in an etching process for forming the contact holes. Thus, the contact holes may be partially connected to each other. When contacts are formed in the contact holes partially connected to each other, the contact may also be connected to each other, thereby causing an electrical short between the contacts. Electrical short between the contacts may result in an electrical failure of the semiconductor device.

### SUMMARY OF THE INVENTION

Example embodiments of the present invention provide a mask structure capable of more precisely forming a desired structure, for example, a trench, a contact hole, or a pattern.

Example embodiments of the present invention provide a method of forming a mask structure employed in the formation of a desired structure, for example, a trench, a contact hole, or a pattern.

Example embodiments of the present invention provide a method of forming a pattern using a mask structure.

Example embodiments of the present invention provide a method of forming contact holes in a semiconductor device using a mask structure.

According to an example embodiment of the present invention, there is provided a mask structure including a first mask pattern and a second mask pattern. The first mask pattern may be formed on an object including a first material. The first mask pattern may include a second material. The second mask pattern may include a third material. The second mask pattern may be formed on the object. The second mask pattern may have a first opening and a second opening that expose portions of the object adjacent to both sides of the first mask pattern.

In an example embodiment of the present invention, the object may include a semiconductor substrate, an insulation layer, a dielectric layer and/or a conductive layer.

In example embodiments of the present invention, the first material may include an oxide, a nitride, a metal oxide, a metal, doped polysilicon and/or a metal nitride. The second material may include an oxide, a nitride, an oxynitride, a metal, a metal oxide, a metal nitride, polysilicon and/or doped polysilicon. The third material may include photoresist, an oxide, a nitride, an oxynitride, a metal, a metal oxide, a metal nitride, polysilicon and/or doped polysilicon.

Examples of oxides may include boro-phophor silicate glass (BPSG), phosphor silicate glass (PSG), undoped silicate glass (USG), spin on glass (SOG), flowable oxide (FOX), tetraethylorthosilicate (TEOS), plasma enhanced-tetraethylorthosilicate (PE-TOES) or high density plasma-chemical vapor deposition (HDP-CVD) oxide. An example of a nitride may include silicon nitride. Examples of oxynitrides may include silicon oxynitride, titanium oxynitride, titanium aluminum oxynitride, tungsten oxynitride or tantalum oxynitride. Examples of metal oxides may include hafnium oxide, zirconium oxide, tantalum oxide, yttrium oxide, niobium oxide, barium titanium oxide or strontium titanium oxide. Examples of metals may include tungsten, titanium, aluminum, copper or tantalum. Examples of metal nitrides may include tungsten nitride, titanium nitride, aluminum nitride, titanium aluminum nitride, tantalum nitride, titanium silicon nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride or tantalum aluminum nitride.

In an example embodiment of the present invention, the first mask pattern may have a first thickness and a first width, and the second mask pattern may have a second thickness, substantially the same as or thinner than the first thickness. The second opening and the third opening may have a second width and a third width, substantially wider than the first width.

According to an example embodiment of the present invention, there is provided a method of forming a mask structure. In a method of forming a hard mask structure, a first mask pattern including a second material may be formed on an object including a first material. A second mask pattern including a third material may be formed on the object. The second mask pattern may have a first opening and a second opening that expose portions of the object adjacent to both sides of the first mask pattern.

In an example embodiment of the present invention, the first mask pattern may be formed by forming a first mask layer on the object, by forming a first photoresist pattern on the first mask layer, and by etching the first mask layer using the first photoresist pattern as an etching mask to form the first mask pattern. The first mask layer may be formed by a chemical vapor deposition (CVD) process, a plasma enhanced chemical vapor deposition (PECVD) process, a high density plasma-chemical vapor deposition (HDP-CVD) process, an atomic layer deposition (ALD) process or a pulsed laser deposition (PLD) process.

In an example embodiment of the present invention, the second mask pattern may be formed by forming a second mask layer on the object to cover the first mask pattern, and by forming the first and the second openings through the second mask layer by partially etching the second mask layer. The second mask layer may be formed by a spin coating process, a CVD process, a PECVD process, an HDP-CVD process, an ALD process, a sputtering process or a PLD process.

In an example embodiment of the present invention, the first and the second openings may be formed by exposing the second mask layer to a light, and by developing the exposed second mask layer.

In an example embodiment of the present invention, the first and the second openings may be formed by forming a second photoresist pattern on the second mask layer, and by partially etching the second mask layer using the second photoresist pattern as an etching mask.

According to an example embodiment of the present invention, there is provided a method of forming a pattern. In a method of forming a pattern, a layer including a first material may be formed on a substrate. A first mask pattern including a second material may be formed on the layer. A second mask pattern including a third material may be formed on the layer. The second mask pattern may have a first opening and a second opening that expose portions of the layer adjacent to both sides of the first mask pattern. The pattern may be formed by etching the layer using the first and the second mask patterns as etching masks.

In an example embodiment of the present invention, the layer may include an insulation material and/or a conductive material.

In an example embodiment of the present invention, the first mask pattern may be formed by forming a first mask layer on the layer, by forming a first photoresist pattern on the first mask layer, and by etching the first mask layer using the first photoresist pattern as an etching mask to form the first mask pattern.

In an example embodiment of the present invention, the second mask pattern may be formed by forming a second mask layer on the layer to cover the first mask pattern, and by forming the first and the second openings through the second mask layer by partially etching the second mask layer.

In an example embodiment of the present invention, the first and the second openings may be formed by exposing the second mask layer to a light, and by developing the exposed second mask layer.

In an example embodiment of the present invention, the first and the second openings may be formed by forming a second photoresist pattern on the second mask layer, and by partially etching the second mask layer using the second photoresist pattern as an etching mask.

In an example embodiment of the present invention, the first and the second mask patterns may be removed after forming the pattern. The first and the second mask patterns may be removed by an ashing process, a stripping process or a chemical mechanical polishing (CMP) process.

According to an example embodiment of the present invention, there is provided a method of forming contacts in a semiconductor device. In a method of forming contacts in a semiconductor device, an insulation layer including a first material may be formed on a substrate having contact regions. A first mask pattern including a second material may be formed on the insulation layer. A second mask pattern including a third material may be formed on the insulation layer. The second mask pattern may have a first opening and a second opening that expose portions of the insulation layer adjacent to both sides of the first mask pattern. Contact holes exposing the contact regions may be formed by partially etching the exposed portions of the insulation layer using the first and the second mask patterns as etching masks. The contacts may be formed in the respective contact holes.

In an example embodiment of the present invention, after forming the contact holes, the first and the second mask patterns may be removed by an ashing process, a stripping process or a CMP process.

According to an example embodiment of the present invention, the mask structure may have the first mask pattern and the second mask pattern including the material substantially different from that of the first mask pattern. Thus, a desired structure, for example, recesses, trenches, contact holes or patterns, may be more precisely formed on or through the object, for example, a substrate, an insulation layer, a dielectric layer or a conductive layer by an etching process using the hard mask structure as an etching mask even through the desired structure is fairly small. For example, the first mask pattern may effectively protect the underlying object or an underlying layer in an etching process for forming contact holes so that the contact holes may not be connected to each other when the contact holes have bar shapes or line shapes. In case that the object may correspond to the conductive layer, conductive patterns having desired sizes may be more accurately formed using a mask structure without an electrical failure between the conductive patterns.

### BRIEF DESCRIPTION OF THE DRAWINGS

Example embodiments of the present invention will become more apparent with the description of example embodiments thereof with reference to the accompanying drawings, in which:

FIG. 1 is an electron microscopic picture illustrating a contact in a conventional semiconductor device;

FIG. 2 is a cross-sectional view illustrating a mask structure in accordance with an example embodiment of the present invention;

FIGS. 3A to 3C are cross-sectional views illustrating a method of forming a mask structure in accordance with an example embodiment of the present invention;

FIGS. 4A to 4F are cross-sectional views illustrating a method of forming a pattern in accordance with an example embodiment of the present invention; and

FIGS. 5A to 5D are cross-sectional views illustrating a method of forming contacts in a semiconductor device in accordance with an example embodiment of the present invention.

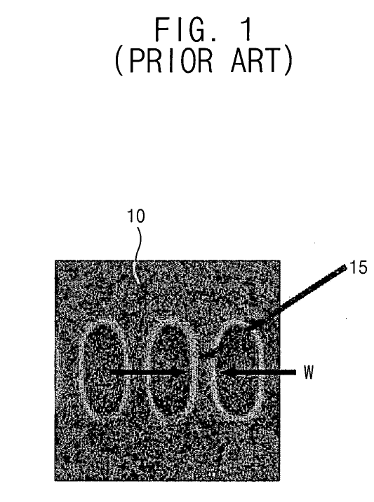

### DESCRIPTION OF EXAMPLE EMBODIMENTS OF THE INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

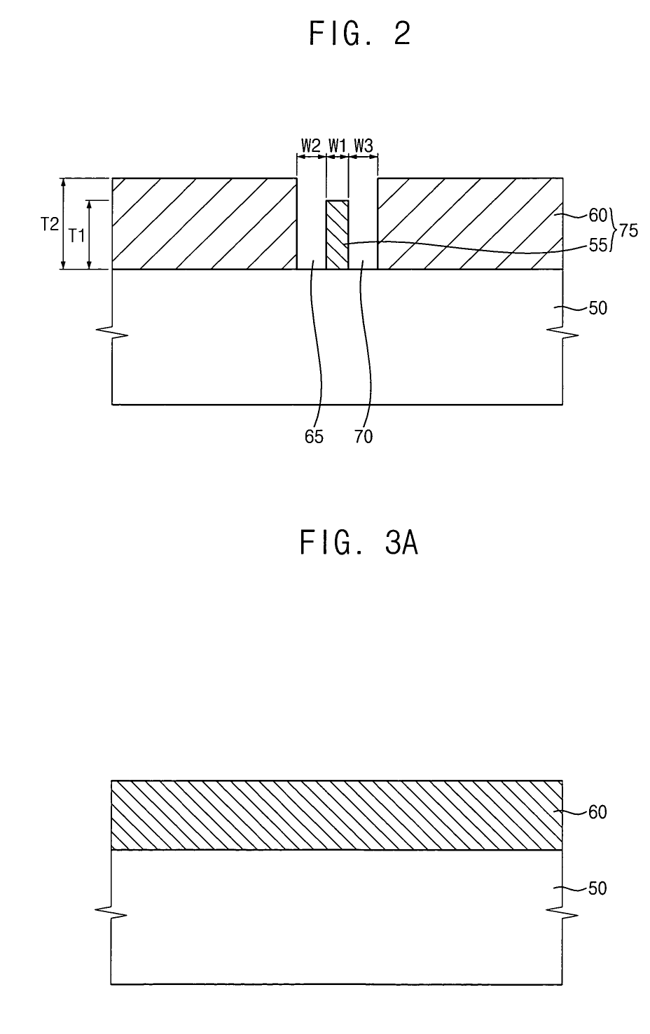

FIG. 2 is a cross-sectional view illustrating a mask structure in accordance with an example embodiment of the present invention.

Referring to FIG. 2, a mask structure 75 may include a first mask pattern 55 and a second mask pattern 60 on a layer 50 to be etched.

The layer 50 may include a first material having a first etching rate relative to an etching solution or an etching gas. The layer 50 may include, for example, a substrate, an insulation layer, a dielectric layer and/or a conductive layer.

In an example embodiment of the present invention, when the layer 50 is a substrate, the layer 50 may include, for example, a silicon wafer, a silicon-on-insulator substrate, or a single crystalline metal oxide substrate.

In another example embodiment of the present invention, the first material of the layer 50 may include an oxide, a nitride or a metal oxide when the layer 50 is an insulation layer and/or a dielectric layer. Examples of the oxide in the first material may include boro-phosphor silicate glass (BPSG), phosphor silicate glass (PSG), undoped silicate glass (USG), spin on glass (SOG), tetraethylorthosilicate (TEOS), flowable oxide (FOX), plasma enhanced-TEOS (PE-TEOS), high density plasma-chemical vapor deposition (HDP-CVD) oxide, etc. An example of the nitride in the first material may include silicon nitride. Examples of the metal oxide in the first material may include hafnium oxide (HfO₂), zirconium oxide (ZrO₂), tantalum oxide (Ta₂O₅), yttrium oxide (Y₂O₃), niobium oxide (NbO₂), barium titanium oxide (BaTiO₃), strontium titanium oxide (SrTiO₃), etc.

In still another example embodiment of the present invention, the first material of the layer 50 may include a metal, a metal nitride, or polysilicon doped with impurities when the layer 50 is a conductive layer. Examples of the metal in the first material may include tungsten (W), titanium (Ti), aluminum (Al), copper (Cu), tantalum (Ta), etc. Examples of the metal nitride in the first material may include tungsten nitride (WN), titanium nitride (TiN), aluminum nitride (AlN), titanium aluminum nitride (TiAlN), tantalum nitride (TaN), titanium silicon nitride (TiSiN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), etc.

The first mask pattern 55 may include a second material that has a second etching rate substantially different from the first etching rate of the first material. In other words, the second material may have an etching selectivity relative to the first material. The first mask pattern 55 may have a first thickness T1 and a first width W1. The first thickness T1 of the first mask pattern 55 may vary in accordance with types of etching solutions or etching gases used in an etching process to etch the layer 50.

In an example embodiment of the present invention, when the layer 50 is a substrate, the second material of the first mask pattern 55 may include an oxide, a nitride, an oxynitride, a metal oxide, polysilicon, doped polysilicon, a metal, a metal nitride, etc. For example, the second material may include, for example, BPSG, PSG, USG, SOG, TEOS, PE-TEOS, HDP-CVD oxide, silicon nitride, silicon oxynitride, hafnium oxide, zirconium oxide, tantalum oxide, yttrium oxide, niobium oxide, barium titanium oxide, strontium titanium oxide, tungsten, titanium, aluminum, copper, tantalum, tungsten nitride, titanium nitride, aluminum nitride, titanium aluminum nitride, tantalum nitride, titanium silicon nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, etc.

In another example embodiment of the present invention, when the layer 50 is an insulation layer or a dielectric layer, the second material of the first mask pattern 55 may include, for example, an oxide, a nitride, a metal oxide, etc. For example, the second material of the first mask pattern 50 may include BPSG, PSG, USG, SOG, FOX, TEOS, PE-TEOS, HDP-CVD oxide, silicon nitride, hafnium oxide, zirconium oxide, tantalum oxide, yttrium oxide, niobium oxide, barium titanium oxide, strontium titanium oxide, etc. The second material of the first mask pattern 55 may include, for example, the oxide, the nitride or the metal oxide different from the first material of the layer 50. Additionally, the second material of the first mask pattern 55 may include, for example, an oxynitride, polysilicon, doped polysilicon, a metal, a metal nitride, etc. For example, the second material may include silicon oxynitride (SiON), titanium oxynitride (TiON), titanium aluminum oxynitride (TiAlON), tungsten oxynitride (WON), tantalum oxynitride (TaON), tungsten, titanium, aluminum, copper, tantalum, tungsten nitride, titanium nitride, aluminum nitride, titanium aluminum nitride, tantalum nitride, titanium silicon nitride, titanium boron nitride, zirconium silicon nitride, tungsten silicon nitride, zirconium aluminum nitride, molybdenum silicon nitride, molybdenum aluminum nitride, tantalum silicon nitride, tantalum aluminum nitride, etc.

In still another example embodiment of the present invention, when the layer 50 is a conductive layer, the second material of the first mask pattern 55 may include, for example, an oxide, a nitride, an oxynitride, a metal oxide, polysilicon, etc. In addition, the second material of the first mask pattern 55 may include, for example, a metal, a metal nitride, doped polysilicon, etc. The second material may include the metal, the metal nitride or doped polysilicon different from the first material. For example, the second material of the first mask pattern 55 may include tungsten, titanium, aluminum, copper, tantalum, tungsten nitride, titanium nitride, aluminum nitride, titanium aluminum nitride, tantalum nitride, titanium silicon nitride, titanium boron nitride, zirconium silicon nitride, tungsten silicon nitride, zirconium aluminum nitride, molybdenum silicon nitride, molybdenum aluminum nitride, tantalum silicon nitride, tantalum aluminum nitride, etc.

Referring now to FIG. 2, the second mask pattern 60 may include a first opening 65 and a second opening 70 formed adjacent to the first mask pattern 55. The second mask pattern 60 may be formed on the layer 50 to surround the first mask pattern 55. The first and the second openings 65 and 70 may expose portions of the layer 50 to be etched. The first and the second openings 65 and 70 may have line, linear, or track shapes. The second mask pattern 60 may have a second thickness T2, substantially thicker than the first thickness T1 of the first mask pattern 55. Alternatively, the second thickness T2 of the second mask pattern 60 may be substantially the same as the first thickness T1 of the first mask pattern 55. The first opening 65 may have a second width W2 and the second opening 70 may have a third width W3. The second and the third widths W2 and W3 may be substantially wider than the first width W1 of the first mask pattern 55. The second width W2 may be substantially the same as or different from the third width W3. However, the first and the second opening 65 and 70 may have widths varied in accordance with a structure or a function of portions of the layer 50 to be etched.

The second mask pattern 60 may include a third material that has a third etch rate substantially different from the first etch rate of the first material and the second etch rate of the second material.

In an example embodiment of the present invention, when the layer 50 is a substrate, the third material of the second mask pattern 60 may include an oxide, a nitride, an oxynitride, a metal oxide, polysilicon, doped polysilicon, a metal or a metal nitride, which are substantially the same as the second material of the first mask pattern 55. Additionally, the second material of the second mask pattern 60 may include photoresist.

In another example embodiment of the present invention, when the object 50 is an insulation layer or a dielectric layer, the third material of the second mask pattern 60 may include an oxide, a nitride or a metal oxide, which is substantially the same as the second material of the first mask pattern 55. For example, when the first material of the object 50 includes the oxide and the second material of the first mask pattern 55 includes the nitride, the third material of the second mask pattern 60 may include the metal nitride or photoresist. Further, the first to the third materials may include one of an oxide, a nitride, and a metal oxide.

In still another example embodiment of the present invention, when the object 50 is a conductive layer, the third material of the second mask pattern 60 may include, for example, an oxide, a nitride, an oxynitride, a metal oxide, polysilicon, etc. Additionally, the first to the third materials may include metal and/or metal nitride materials.

As described above, the mask structure 75 may include the first mask pattern 55 of the second material and the second mask pattern 60 of the third material so that a desired structure may be more precisely formed in or through the layer 50 using the mask structure 75 in the etching process for etching the layer 50 to form smaller structures, for example, trenches, recesses, grooves or holes in layer object 50. When a hole having a bar shape or a line shape is formed through the layer 50 using the mask structure 75, adjacent holes may not be partially connected to each other because the first mask pattern 55 effectively protects a portion of the layer 50 positioned thereunder. When the layer 50 is a conductive layer, finer conductive patterns having bar shapes or line shapes may be more accurately formed by etching the layer 50 using the mask structure 75 without an electrical short caused by a connection or a bridge between the fine conductive patterns.

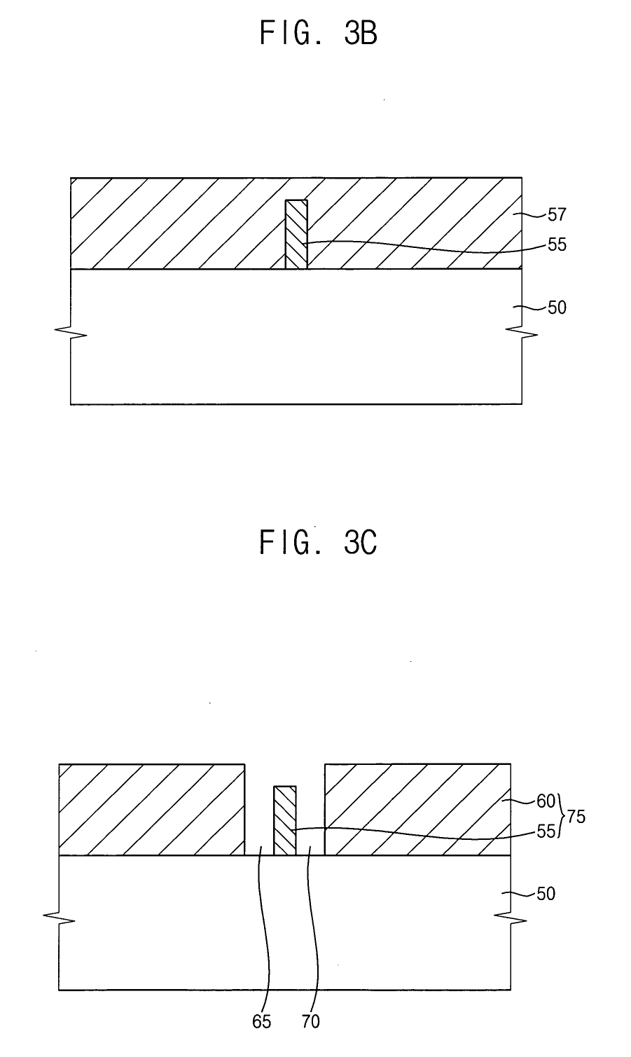

FIGS. 3A to 3C are cross-sectional views illustrating a method of forming a mask structure in accordance with example embodiments of the present invention.

Referring to FIG. 3A, a first mask layer 53 may be formed on an object 50 including a first material. The object 50 may correspond, for example, to a semiconductor substrate, an insulation layer, a dielectric layer, or a conductive layer. The first material may have a first etch rate relative to an etching solution or an etching gas for etching the object 50.

The first mask layer 53 may be formed, for example, by a chemical vapor deposition (CVD) process, a plasma enhanced chemical vapor deposition (PECVD) process, an atomic layer deposition (ALD) process, a sputtering process, a pulse laser deposition (PLD) process, etc.

The first mask layer 53 may be formed using a second material substantially different from the first material. The second material may have a second etch rate with respect to the etching solution or the etching gas for etching the object 50. For example, the first material may include an oxide, and the second material may include a nitride, an oxynitride and/or polysilicon.

Referring to FIG. 3B, after a first photoresist pattern (not shown) is formed on the first mask layer 53, the first mask layer 53 is etched using the first photoresist pattern as an etching mask. Thus, a first mask pattern 55 is formed on the object 50. The first photoresist pattern may be removed by an ashing process and/or a stripping process.

A second mask layer 57 may be formed on the object 50 to cover the first mask pattern 55. In an example embodiment of the present invention, the second mask layer 57 may completely cover the first mask pattern 55. That is, the second mask layer 57 may have a thickness substantially thicker than a thickness of the first mask pattern 55 so that the first mask pattern 55 is buried in the second mask layer 57. In another example embodiment of the present invention, the second mask layer 57 may have a height substantially the same as that of the first mask pattern 55. Namely, the first mask pattern 55 may be exposed after the formation of the second mask layer 57.

The second mask layer 57 may be formed using a third material different from the first material and the second material. The third material may have a third etch rate different from the first etch rate of the first material and the second etch rate of the second material. When the object 50 includes an oxide and the first mask pattern 55 includes a nitride, the second mask layer 57 may include photoresist, an oxynitride, polysilicon, etc.

The second mask layer 57 may be formed by, for example, a spin coating process, a CVD process, a PECVD process, an ALD process, an HDP-CVD process, a sputtering process, a PLD process, etc.

Referring to FIG. 3C, the second mask layer 57 may be partially etched to form a second mask pattern 60 having a first opening 65 and a second opening 70 adjacent to both sides of the first mask pattern 55. That is, portions of the second mask layer 57 adjacent to the first mask pattern 55 are etched to form the second mask pattern 60.

When the second mask pattern 60 having the first and the second openings 65 and 70 is formed, first portions of the object 50 may be exposed through the first and the second openings 65 and 70, whereas a second portion of the object 50 beneath the first mask pattern 55 is not exposed.

When the third material of the second mask layer 57 includes photoresist according to an example embodiment of the present invention, the second mask layer 57 may be exposed and developed to thereby form the second mask layer 60 surrounding the first mask pattern 55 on the object 50.

When the second mask layer 57 includes the oxide, the oxynitride, the metal oxide, the metal, the metal nitride, polysilicon and/or doped polysilicon, a second photoresist pattern (not shown) may be formed on the second mask layer 57. The second mask layer 57 may be etched using the second photoresist pattern as an etching mask, thereby forming the second mask pattern 60 on the object 50. The second photoresist pattern may be removed by an ashing process and/or a stripping process.

After the second mask pattern 60 is formed, a mask structure 75 having the first and the second mask patterns 55 and 60 may be complete on the object 50. In an etching process for etching the exposed first portions of the object 50 using the mask structure 75, the first mask pattern 55 effectively protects the second portion of the object 50 so that a desired structure including, for example, trenches, holes, recesses or grooves may be more precisely formed by etching the object 50. When the object 50 is a conductive layer, conductive patterns may be more accurately formed by etching the object 50 without an electrical failure caused by a connection between the conductive patterns. Thus, an electrical short between the conductive patterns may be reduce or prevented.

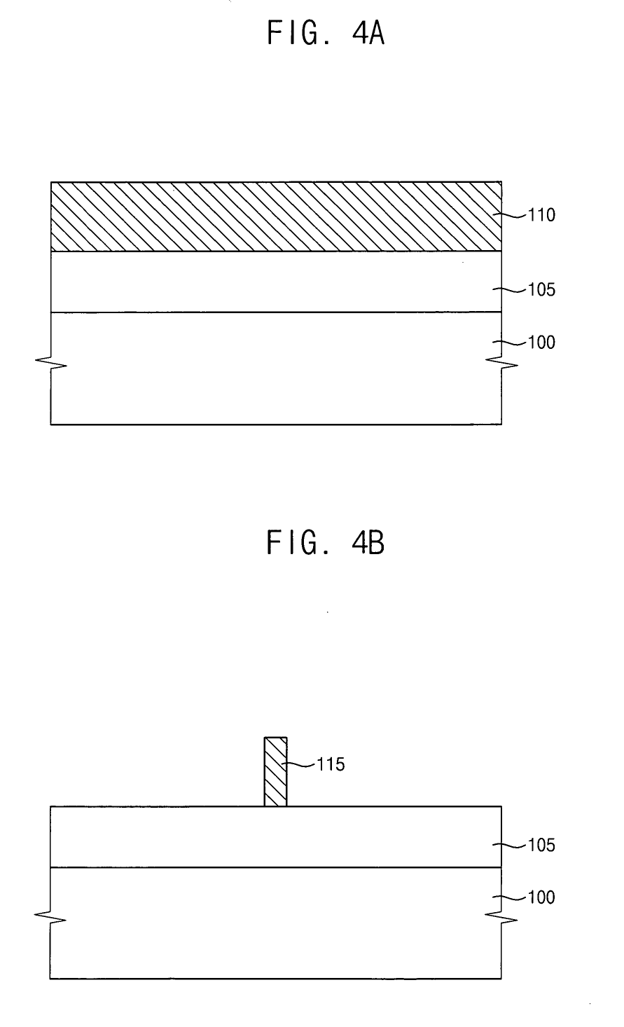

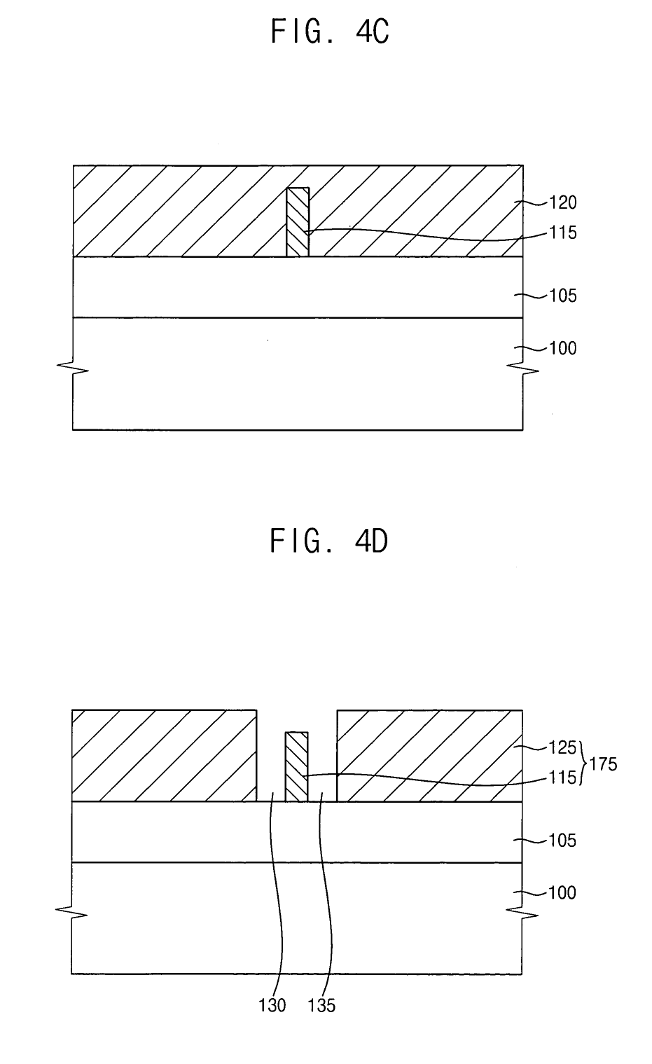

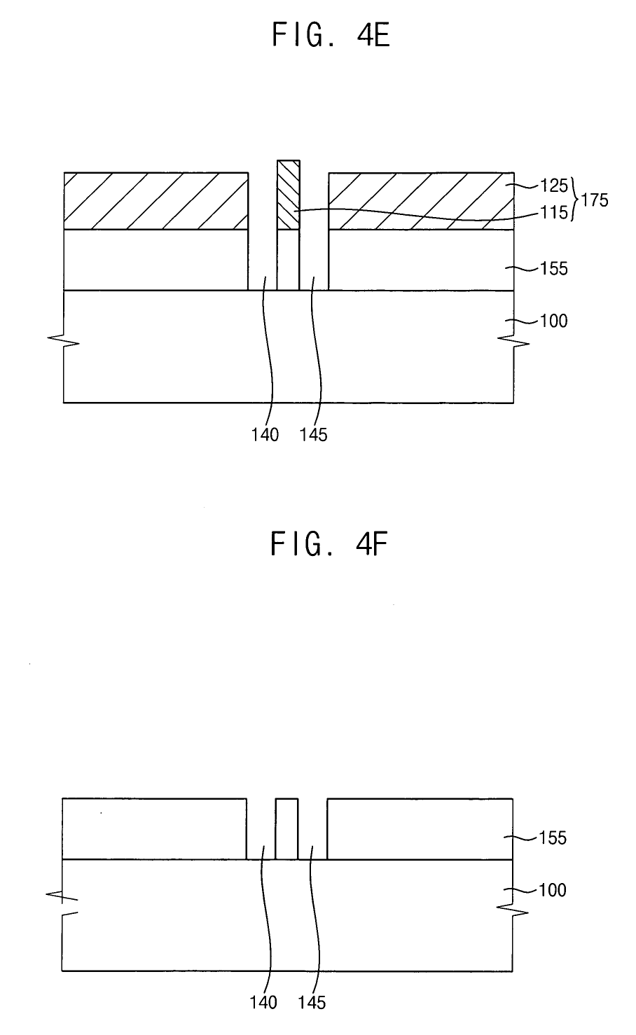

FIGS. 4A to 4F are cross-sectional views illustrating a method of forming a pattern in accordance with example embodiments of the present invention.

Referring to FIG. 4A, a layer 105 to be patterned is formed on a semiconductor substrate 100. The semiconductor substrate 100 may include, for example, a silicon wafer, an SOI substrate, or a single crystalline metal oxide substrate. A lower structure (not shown) may be formed on the semiconductor substrate 100. The lower structure may include a contact region, a conductive pattern, a conductive wiring, an insulation pattern, a gate structure, a spacer and/or a transistor.

The layer 105 to be patterned may be formed on the substrate 100 to cover the lower structure. The layer 105 may be formed using a first material that has a first etching rate with respect to predetermined or desired etching solutions and predetermined or desired etching gases. The layer 105 may be formed by, for example, a CVD process, a PECVD process, an HDP-CVD process, an ALD process, a sputtering process, a PLD process, etc.

In an example embodiment of the present invention, the first material of the layer 105 may include an insulation material. For example, the first material may include an oxide such as BPSG, PSG, SOG, USG, TEOS, PE-TEOS, HDP-CVD oxide, etc. Alternatively, the first material may include a nitride, for example, silicon nitride. Furthermore, the first material may include a metal oxide, for example, hafnium oxide, zirconium oxide, tantalum oxide, yttrium oxide, niobium oxide, barium titanium oxide, strontium ruthenium oxide, etc.

In another example embodiment of the present invention, the first material of the layer 105 may include a conductive material such as polysilicon doped with impurities, a metal or a metal nitride. For example, the first material may include tungsten, tungsten nitride, titanium, titanium nitride, aluminum, aluminum nitride, titanium aluminum nitride, copper, tantalum, tantalum nitride, titanium silicon nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, and/or tantalum aluminum nitride.

Referring now to FIG. 4A, a first mask layer 110 may be formed on the layer 105 to be patterned. The first mask layer 110 may be formed using a second material that has a second etch rate substantially different from the first etch rate of the first material. The second material of the first mask layer 110 may include an oxide, a nitride, an oxynitride, a metal oxide, polysilicon, doped polysilicon, a metal and/or a metal nitride. The first mask layer 110 may be formed by, for example, a CVD process, a PECVD process, an HDP-CVD process, a sputtering process, a PLD process, etc.

In an example embodiment of the present invention, the second material of the first mask layer 110 may include polysilicon, doped polysilicon, the metal oxide, the metal, the metal nitride, the nitride and/or the oxynitride when the layer 105 includes an oxide.

In another example embodiment of the present invention, the second material of the first mask layer 110 may include polysilicon, doped polysilicon, the metal oxide, the metal, the oxide, the metal nitride and/or the oxynitride when the layer 105 includes a nitride.

In another example embodiment of the present invention, the second material of the first mask layer 110 may include polysilicon, doped polysilicon, the oxide, the nitride, the metal, the metal nitride, and/or the oxynitride when the layer 105 includes a metal oxide.

In another example embodiment of the present invention, the second material of the first mask layer 110 may include the oxide, the nitride, the oxynitride, polysilicon and/or the metal oxide when the layer 105 includes conductive material, for example, a metal or metal nitride.

The first mask layer 110 may have a thickness varied in accordance with types of the predetermined or desired etching solutions or the predetermined or desired etching gases for etching the layer 105.

In an example embodiment of the present invention, the thickness of the first mask layer 110 may increase as the thickness of the layer 105 increases. When the layer 105 includes the oxide or the nitride and the first hard mask layer 110 includes polysilicon, the oxide, the nitride and/or the metal, the first mask layer 110 may have an increased thickness in accordance with an increase of the thickness of the layer 105 so as to sufficiently etch the layer 105.

In another example embodiment of the present invention, the thickness of the first mask layer 105 may not vary even though the layer 105 has an increased thickness. When the first mask layer 110 includes the metal oxide or the oxynitride and the layer 105 includes the oxide, the nitride, the metal and/or the metal nitride, the first mask layer 110 may have a substantially constant thickness though the thickness of the layer 105 increases.

Referring to FIG. 4B, after a first photoresist pattern (not shown) is formed on the first mask layer 110, the first mask layer 110 may be etched using the first photoresist pattern as an etching mask. Thus, a first mask pattern 115 is formed on the layer 105. The first mask pattern 115 may have a width varied in accordance with a size of a layer pattern 140 (see FIG. 4E) formed using the first mask pattern 115. The layer pattern 140 may include bar-shaped openings, line-shaped openings, recesses and/or trenches.

Referring to FIG. 4C, the first photoresist pattern may be removed from the first mask pattern 115 by an ashing process and/or a stripping process. A second mask layer 120 may be formed on the layer 105 to cover the first mask pattern 115.

In an example embodiment of the present invention, the second mask layer 120 may completely cover the first mask pattern 110. That is, the second mask layer 120 may have a thickness sufficiently thicker than that of the first mask pattern 115 so that the second mask layer 120 may completely cover the first mask pattern 115. In other words, the first mask pattern 115 is buried in the second mask layer 120.

In another example embodiment of the present invention, the second mask layer 120 may have a thickness substantially the same as that of the first mask pattern 115. Here, an upper portion or upper face of the first mask pattern 115 may be exposed after the formation of the second mask layer 120.

The second mask layer 120 may include a third material that has an etch rate substantially different from the first etch rate of the first material and the second etch rate of the second material. The second mask layer 120 may be formed by, for example, a spin coating process, a PECVD process, an ALD process, an HDP-CVD process, a sputtering process, a PLD process, etc.

In an example embodiment of the present invention, the third material of the second mask layer 120 may include photoresist when the layer 105 and the first mask pattern 115 independently include the oxide, the nitride, the oxynitride and/or the metal oxide. Alternatively, the third material of the second mask layer 120 may include the oxide, the nitride, the oxynitride and/or the metal oxide different from those of the first and the second materials. For example, the second mask layer 120 may include the oxynitride or the metal oxide when the layer 105 and the first mask pattern 115 include the oxide and the nitride, respectively.

In another example embodiment of the present invention, the third material of the second mask layer 120 may include the metal oxide when the layer 105 includes doped polysilicon, the metal and/or the metal nitride, and the first mask pattern 115 includes polysilicon, the oxide, the nitride and/or the oxynitride. Alternatively, the third material of the second mask layer 120 may include the metal, the metal nitride, the oxynitride, the oxide, the nitride, polysilicon and/or doped polysilicon different from those of the first and the second materials.

Referring to FIG. 4D, when the second mask layer 120 includes photoresist, the second mask layer 120 may be exposed to a light, and developed to thereby form a second mask pattern 125 having a first opening 130 and a second opening 135. The first and the second openings 130 and 135 may expose portions of the layer 105 adjacent to both sides of the first mask pattern 115. That is, both sides of the first mask pattern 115 may be exposed by the first and the second openings 130 and 135.

When the second mask layer 120 includes the oxide, the nitride, the oxynitride, the metal oxide, the metal, the metal nitride, polysilicon and/or doped polysilicon, a second photoresist pattern (not shown) may be formed on the second mask layer 120. The second mask layer 120 may be etched using the second photoresist pattern as an etching mask. Hence, the second mask pattern 125 having the first and the second openings 130 and 135 is formed on the layer 105. When the second mask pattern 125 is formed to enclose the first mask pattern 115, a mask structure 175 having the first and the second mask patterns 115 and 125 is formed on the layer 105 as shown in FIG. 4D.

Referring to FIG. 4E, the exposed portions of the layer 105 through the first and the second openings 130 and 135 are etched using the mask structure 175 as an etching mask. Thus, a layer pattern 155 having contact holes 140 and 145, recesses or trenches may be formed. The contact holes 140 and 145 may have desired shapes, for example, line shapes or bar shapes. The layer pattern 155 may be formed by, for example, a dry etching process. In the etching process for forming the layer pattern 155, the first mask pattern 115 may protect a portion of the layer 105 between the contact holes 140 and 145 so that the contact holes 140 and 145 may be accurately formed without being connecting to each other. When the second mask pattern 125 includes photoresist, the second mask pattern 125 may be consumed during the etching process for forming the layer pattern 155.

Referring to FIG. 4F, the mask structure 175 having the first and the second mask patterns 115 and 125 may be removed from the layer pattern 155 by an ashing process, a stripping process or a chemical mechanical polishing (CMP) process. Therefore, the layer pattern 155 may be completed on the substrate 100.

In an example embodiment of the present invention, the second mask pattern 125 may be removed by an ashing process and/or a stripping process, and the first mask pattern 115 may be removed by a CMP process.

In another example embodiment of the present invention, the first and the second mask patterns 115 and 125 may be simultaneously removed from the layer pattern 155 by a CMP process.

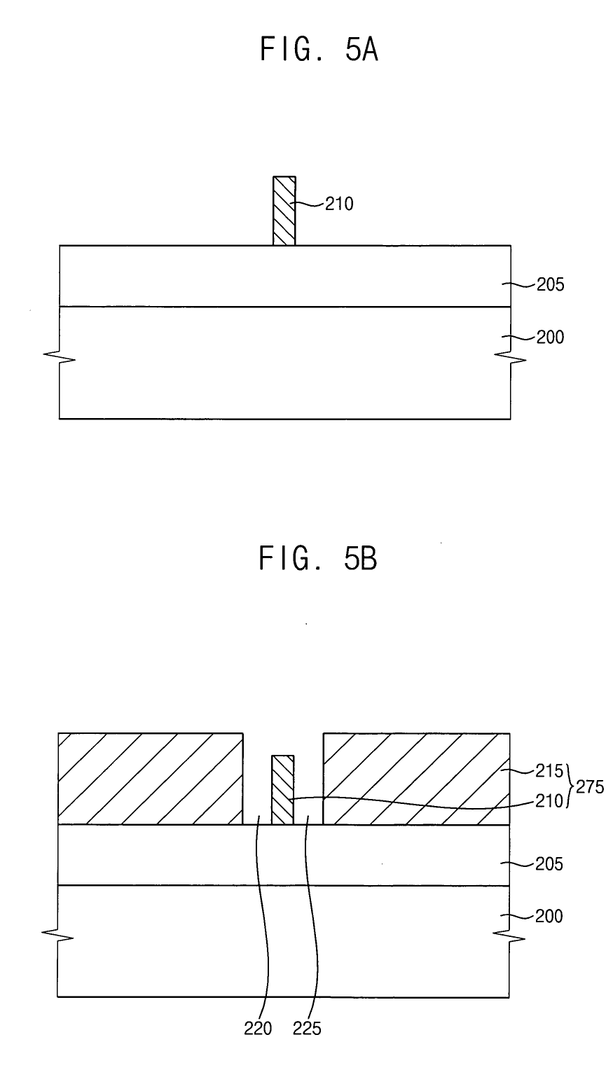

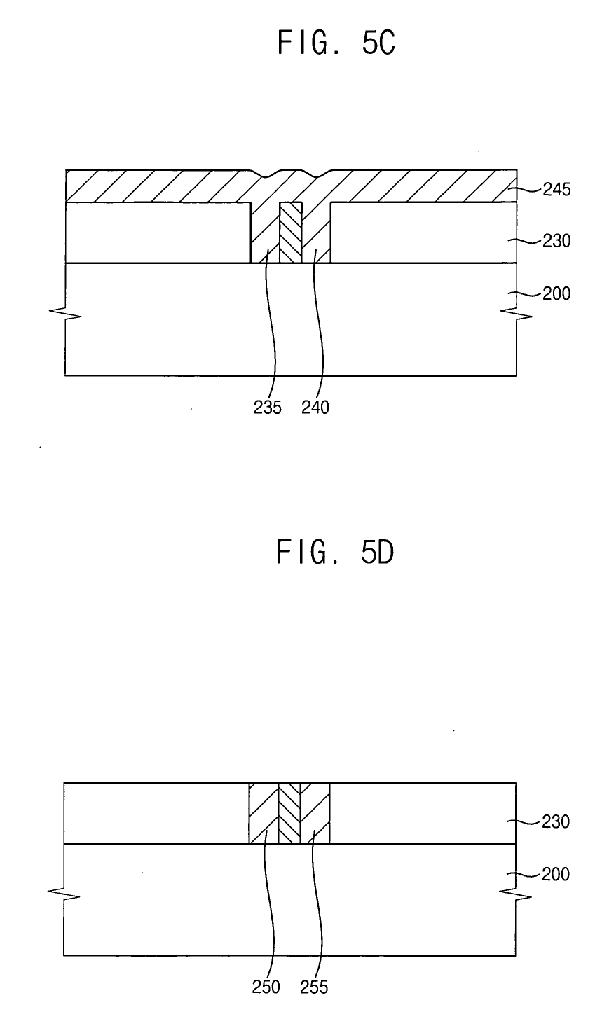

FIGS. 5A to 5D are cross-sectional views illustrating a method of forming contacts in a semiconductor device in accordance with example embodiments of the present invention.

Referring to FIG. 5A, an insulation layer 205 to be patterned may be formed on a semiconductor substrate 200 using an oxide. For example, the insulation layer 205 may be formed using BPSG, PSG, SOG, USG, FOX, TEOS, PE-TEOS, HDP-CVD oxide, etc. A lower structure (not shown) may be formed on the semiconductor substrate 200. The lower structure may include a contact region, a conductive pattern, a conductive wiring, an insulation pattern, a gate structure, a spacer and/or a transistor. The insulation layer 205 may be formed on the substrate 200 to cover the lower structure. The insulation layer 205 may be formed by, for example, a CVD process, a PECVD process, an HDP-CVD process, an ALD process, a PLD process, etc.

After a first mask layer is formed on the insulation layer 205, a first photoresist pattern (not shown) may be formed on the first mask layer. The first mask layer may be etched using the first photoresist pattern as an etching mask to thereby form a first mask pattern 210 on the insulation layer 205. The first mask layer may be formed using a material different from the oxide of the insulation layer 205. For example, the first mask layer may be formed using a nitride, an oxynitride, polysilicon, doped polysilicon, a metal and/or a metal nitride. Additionally, the first mask layer may be formed by, for example, a CVD process, an ALD process, a PECVD process, an HDP-CVD process, a sputtering process, a PLD process etc.

Referring to FIG. 5B, after the first photoresist pattern is formed by an ashing process and/or a stripping process, a second first mask layer may be formed on the insulation layer 205 to cover the first mask pattern 210.

The second mask layer may be partially etched to form a first opening 220 and a second opening 225 through the second mask layer. Thus, a second mask pattern 215 having the first and the second openings 220 and 225 may be formed on the insulation layer 205. The first and the second openings 220 and 225 may expose portions of the insulation layer 205 adjacent to sides of the first mask pattern 210.

The second mask layer may be formed using a material different from that of the first mask layer and that of the insulation layer 205. The second mask layer may be formed by, for example, a spin coating process, a PECVD process, an ALD process, an HDP-CVD process, a sputtering process, a PLD process, etc.

When the second mask layer includes photoresist, the second mask layer may be exposed to light and developed to thereby form the second mask pattern 215 having the first and the second openings 220 and 225.

When the second mask layer includes a nitride, an oxynitride, a metal oxide, a metal, a metal nitride, polysilicon or doped polysilicon, a second photoresist pattern (not shown) may be formed on the second mask layer. The second mask layer may be etched using the second photoresist pattern as an etching mask so that the second mask pattern 215 is formed on the insulation layer 205. When the second mask pattern 215 is formed to enclose the first mask pattern 210, a mask structure 275 having the first and the second mask patterns 210 and 215 is formed on the insulation layer 205 as shown in FIG. 5B.

Referring to FIG. 5C, the exposed portions of the insulation layer 205 through the first and the second openings 220 and 225 may be etched using the mask structure 275 as an etching mask. Thus, a first contact hole 235 and a second contact hole 240 having line shapes or bar shapes are formed through the insulation layer 205.

The mask structure 275 having the first and the second mask patterns 210 and 215 may be removed from the insulation layer 205 by, for example, an ashing process, a stripping process or a CMP process.

A conductive layer 245 may be formed on the insulation layer 205 to fill the first and the second contact holes 235 and 240. The conductive layer 245 may be formed, for example, using doped polysilicon, a metal and/or a metal nitride. For example, the conductive layer 245 may be formed using tungsten, titanium, aluminum, copper, tantalum, tungsten nitride, titanium nitride, aluminum nitride, titanium aluminum nitride, tantalum nitride, titanium silicon nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, etc. The conductive layer 245 may be formed b, for example, a sputtering process, a CVD process, an ALD process, a PLD process, etc.

Referring to FIG. 5D, the conductive layer 245 may be partially removed by, for example, a CMP process and/or an etch back process until the insulation layer 205 is exposed. Thus, a first contact 250 and a second contact 255 are formed in the first contact hole 235 and the second contact hole 240, respectively.

According to example embodiments of the present invention, a mask structure may have a first mask pattern and a second mask pattern including a material substantially different from that of the first mask pattern. Thus, a desired structure, for example, recesses, trenches, holes and/or patterns, may be more precisely formed on or through an object such as a substrate, an insulation layer, a dielectric layer or a conductive layer by an etching process using the hard mask structure as an etching mask even through the desired structure has a relatively small size. For example, the first mask pattern may more effectively protect the underlying object or an underlying layer in an etching process for forming contact holes so that the contact holes may not be connected to each other when the contact holes have bar shapes or line shapes. In case that the object may correspond to the conductive layer, conductive patterns having desired sizes may be more accurately formed using the mask structure without an electrical failure between the conductive patterns.

According to example embodiments of the present invention, a mask structure may have N mask patterns, where N>2 with one or more of the mask structures made of substantially different materials.

According to example embodiments of the present invention, a mask structure having N mask patterns may be formed similar to the dual mask patterns described above and may be used to form patterns and contacts in a semiconductor device similar to the dual mask patterns described above.

The foregoing is illustrative of the present invention and is not to be construed as limiting thereof. Although example embodiments of the present invention have been described, those skilled in the art will readily appreciate that many modifications are possible without materially departing from the novel teachings and advantages of example embodiments of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A mask structure comprising:
a first mask pattern including a second material formed on an object including a first material; and
a second mask pattern including a third material formed on the object, the second mask pattern having a first opening and a second opening that expose portions of the object adjacent to both sides of the first mask pattern.

2. The mask structure of claim 1, wherein the object comprises at least one selected from the group consisting of a semiconductor substrate, an insulation layer, a dielectric layer and a conductive layer.

3. The mask structure of claim 1, wherein the first material comprises at least one selected from the group consisting of an oxide, a nitride, a metal oxide, a metal, a doped polysilicon and a metal nitride.

4. The mask structure of claim 3, wherein the second material comprises at least one selected from the group consisting of an oxide, a nitride, an oxynitride, a metal, a metal oxide, a metal nitride, a polysilicon and a doped polysilicon.

5. The mask structure of claim 4, wherein the third material comprises at least one selected from the group consisting of a photoresist, an oxide, a nitride, an oxynitride, a metal, a metal oxide, a metal nitride, a polysilicon and a doped polysilicon.

6. The mask structure of claim 5, wherein the oxide comprises at least one selected from the group consisting of boro-phophor silicate glass (BPSG), phosphor silicate glass (PSG), undoped silicate glass (USG), spin on glass (SOG), flowable oxide (FOX), tetraethylorthosilicate (TEOS), plasma enhanced-tetraethylorthosilicate (PE-TOES) and high density plasma-chemical vapor deposition (HDP-CVD) oxide.

7. The mask structure of claim 5, wherein the nitride comprises silicon nitride, and the oxynitride comprises at least one selected from the group consisting of silicon oxynitride, titanium oxynitride, titanium aluminum oxynitride, tungsten oxynitride and tantalum oxynitride.

8. The mask structure of claim 5, wherein the metal oxide comprises at least one selected from the group consisting of hafnium oxide, zirconium oxide, tantalum oxide, yttrium oxide, niobium oxide, barium titanium oxide and strontium titanium oxide.

9. The mask structure of claim 5, wherein the metal comprises at least one selected from the group consisting of tungsten, titanium, aluminum, copper and tantalum.

10. The mask structure of claim 5, wherein the metal nitride comprises at least one selected from the group consisting of tungsten nitride, titanium nitride, aluminum nitride, titanium aluminum nitride, tantalum nitride, titanium silicon nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride and tantalum aluminum nitride.

11. The mask structure of claim 1, wherein the first mask pattern has a first thickness and a first width, and the second mask pattern has a second thickness substantially the same as or thinner than the first thickness.

12. The mask structure of claim 11, wherein the second opening and the third opening have a second width and a third width, substantially wider than the first width.

13. A method of forming a mask structure, comprising:
forming a first mask pattern including a second material on an object including a first material; and
forming a second mask pattern including a third material on the object, wherein the second mask pattern has a first opening and a second opening that expose portions of the object adjacent to both sides of the first mask pattern.

14. The method of claim 13, wherein forming the first mask pattern further comprises:
forming a first mask layer on the object;
forming a first photoresist pattern on the first mask layer; and
etching the first mask layer using the first photoresist pattern as an etching mask to form the first mask pattern.

15. The method of claim 14, wherein the first mask layer is formed by a chemical vapor deposition (CVD) process, a plasma enhanced chemical vapor deposition (PECVD) process, a high density plasma-chemical vapor deposition (HDP-CVD) process, an atomic layer deposition (ALD) process or a pulsed laser deposition (PLD) process.

16. The method of claim 13, wherein forming the second mask pattern further comprises:
forming a second mask layer on the object to cover the first mask pattern; and
forming the first and the second openings through the second mask layer by partially etching the second mask layer.

17. The method of claim 16, wherein the second mask layer is formed by a spin coating process, a CVD process, a PECVD process, an HDP-CVD process, an ALD process, a sputtering process or a PLD process.

18. The method of claim 16, wherein forming the first and the second openings further comprises:
exposing the second mask layer to a light; and
developing the exposed the second mask layer.

19. The method of claim 16, wherein forming the first and the second openings further comprises:
forming a second photoresist pattern on the second mask layer; and
partially etching the second mask layer using the second photoresist pattern as an etching mask.

20. A method of forming a pattern, comprising:
forming a layer including a first material on a substrate;
forming a first mask pattern including a second material on the layer;
forming a second mask pattern including a third material on the layer, wherein the second mask pattern has a first opening and a second opening that expose portions of the layer adjacent to both sides of the first mask pattern; and
forming the pattern by etching the layer using the first and the second mask patterns as etching masks.

21. The method of claim 20, wherein the layer comprises an insulation material or a conductive material.

22. The method of claim 21, wherein the first material comprises at least one selected from the group consisting of an oxide, a nitride, a metal oxide, a metal, doped polysilicon and a metal nitride, the second material comprises at least one selected from the group consisting of the oxide, the nitride, an oxynitride, the metal, the metal oxide, the metal nitride, polysilicon and the doped polysilicon, and the third material comprises at least one selected from the group consisting of photoresist, the oxide, the nitride, the oxynitride, the metal, the metal oxide, the metal nitride, the polysilicon and the doped polysilicon.

23. The method of claim 22, wherein the oxide comprises at least one selected from the group consisting of BPSG, PSG, USG, SOG, FOX, TEOS, PE-TOES and HDP-CVD oxide, the nitride comprises silicon nitride, the oxynitride comprises at least one selected from the group consisting of silicon oxynitride, titanium oxynitride, titanium aluminum oxynitride, tungsten oxynitride and tantalum oxynitride, and the metal oxide comprises any one selected from the group consisting of hafnium oxide, zirconium oxide, tantalum oxide, yttrium oxide, niobium oxide, barium titanium oxide and strontium titanium oxide.

24. The method of claim 22, wherein the metal comprises at least one selected from the group consisting of tungsten, titanium, aluminum, copper and tantalum, and the metal nitride comprises at least one selected from the group consisting of tungsten nitride, titanium nitride, aluminum nitride, titanium aluminum nitride, tantalum nitride, titanium silicon nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride and tantalum aluminum nitride.

25. The method of claim 20, wherein forming the first mask pattern further comprises:
forming a first mask layer on the layer;
forming a first photoresist pattern on the first mask layer; and
etching the first mask layer using the first photoresist pattern as an etching mask to form the first mask pattern.

26. The method of claim 20, wherein forming the second mask pattern further comprises:
forming a second mask layer on the layer to cover the first mask pattern; and
forming the first and the second openings through the second mask layer by partially etching the second mask layer.

27. The method of claim 26, wherein forming the first and the second openings further comprises:
exposing the second mask layer to a light; and
developing the exposed second mask layer.

28. The method of claim 26, wherein forming the first and the second openings further comprises:
forming a second photoresist pattern on the second mask layer; and
partially etching the second mask layer using the second photoresist pattern as an etching mask.

29. The method of claim 20, further comprising removing the first and the second mask patterns after forming the pattern.

30. The method of claim 29, wherein the first and the second mask patterns are removed by an ashing process, a stripping process or a chemical mechanical polishing (CMP) process.

31. A method of forming contacts in a semiconductor device, comprising:
forming an insulation layer including a first material on a substrate having contact regions;
forming a first mask pattern including a second material on the insulation layer;
forming a second mask pattern including a third material on the insulation layer, wherein the second mask pattern has a first opening and a second opening that expose portions of the insulation layer adjacent to both sides of the first mask pattern;
forming contact holes exposing the contact regions by partially etching the exposed portions of the insulation layer using the first and the second mask patterns as etching masks; and
forming the contacts in the contact holes.

32. The method of claim 31, wherein forming the first mask pattern further comprises:
forming a first mask layer on the insulation layer;
forming a first photoresist pattern on the first mask layer; and
etching the first mask layer using the first photoresist pattern as an etching mask to form the first mask pattern.

33. The method of claim 31, wherein forming the second mask pattern further comprises:
forming a second mask layer on the insulation layer to cover the first mask pattern; and
forming the first and the second openings through the second mask layer by partially etching the second mask layer.

34. The method of claim 33, wherein forming the first and the second openings further comprises:
exposing the second mask layer to a light; and
developing the exposed second mask layer.

35. The method of claim 33, wherein forming the first and the second openings further comprises:
forming a second photoresist pattern on the second mask layer; and
partially etching the second mask layer using the second photoresist pattern as an etching mask.

36. The method of claim 31, further comprising removing the first and the second mask patterns after forming the contact holes by an ashing process, a stripping process or a CMP process.
